(19) United States
(12) Patent Application Publication
(10) Pub. No.: US 2014/0095161 A1
(43) Pub. Date: Apr. 3, 2014

(54) SYSTEM AND METHOD FOR CHANNEL EQUALIZATION USING CHARACTERISTICS OF AN UNKNOWN SIGNAL

(71) Applicant: AT&T INTELLECTUAL PROPERTY I, L.P., Atlanta, GA (US)

(72) Inventors: David Waite, Silver Spring, MD (US); Helen Salter, Columbia, MD (US)

(73) Assignee: AT&T Intellectual Property I, L.P., Atlanta, GA (US)

(21) Appl. No.: 13/630,840

(22) Filed: Sep. 28, 2012

(51) Int. Cl. G01R 23/16; G06F 19/00; G10L 17/00

(52) U.S. Cl. 704/246; 702/76; 704/E17.005

(57) ABSTRACT

Disclosed herein are systems and methods for identifying the source of a signal via channel equalization using characteristics of the signal. A system receives a signal, then measures a frequency response of the signal by performing a spectral analysis over the entire signal. The system computes the average amplitude over a subset of time samples from the spectral analysis for each represented frequency and compares the set of averaged amplitudes to a stored set of averaged amplitudes to produce equalization coefficients. Applying the equalization coefficients to the frequency response yields an equalized frequency response, which is compared to a stored frequency response using a classifier to determine a match. Alternately, the system applies the equalization coefficients to the stored frequency response yielding an equalized stored frequency response. The method can recognize speakers, vehicles, electromagnetic signals, sonar signals, optical signals, videos, etc.

### BACKGROUND

1. Technical Field

The present disclosure relates to a system and a method for identifying the source of a signal and more specifically to equalizing channels using characteristics of the signal.

2. Introduction

Signal identification is used to recognize the origin of signals of interest such as spoken utterances, conversations, sounds, audio, video, sonar, light, and electromagnetic signals. Using speech as an example of the signal processing approach illustrates the issue. Identifying a spoken utterance means to identify the speaker based on the patterns or frequencies of the speaker's voice as measured in a recorded signal. The same is true of identifying sources of other signals, such as identifying a vehicle based on the sound emitted by the engine. In order to identify the origin of a sound, the recorded signal must be compared to some known signal. The signals are compared to determine if the signals match. If the unknown signal matches the known signal, then the two signals originated from the same source, e.g. the spoken utterances are from the same speaker, or the engine sounds are from the same model of vehicle or the same exact vehicle.

Many different communications devices transmit and receive signals. Each of these devices gives a different response at different frequencies, meaning that the amount of amplification can vary from one frequency to another within the same signal. For example, a specific communications device can amplify a high frequency more than a low frequency. When a range of frequencies is viewed together, the amplification of the communications device will vary across the entire range. Because the device modifies the signal based on the varying amplification of the device, signals originating from the same source may not appear the same when compared to each other.

One of the significant problems in signal identification is poor accuracy caused by mismatched channel conditions. The frequency response of a channel can vary from connection to connection for many reasons, including amplifier design, transmission methods, digital compression methods, and differing transmission or communications devices (such as cell phones from different manufacturers, landlines, speakerphones, walkie-talkies, microphones, sonar receivers, cameras, antennas, photocells, etc.). A more accurate method of determining whether two signals originated from the same source when they have been communicated or recorded using different devices is needed.

### BRIEF DESCRIPTION OF THE DRAWINGS

FIG. 1 illustrates an example system embodiment;

FIG. 2 illustrates exemplary signal identification when the equalization coefficients are applied to a frequency response associated with an unknown source;

FIG. 3 illustrates exemplary signal identification when the equalization coefficients are applied to a stored frequency response;

FIG. 4a-4b illustrate exemplary frequency responses from a speaker using different communications devices; and

FIG. 5 illustrates an example method embodiment.

### DETAILED DESCRIPTION

A system, method and non-transitory computer-readable media are disclosed which normalizes channels using characteristics of a signal to improve the accuracy of identifying the source of the signal. A system, configured according to this disclosure, receives a signal associated with an unknown source. The system then measures (estimates) the frequency response of the signal by performing a spectral analysis using a standard method such as a Discrete Fourier Transform (DFT) or a filter bank to produce a mathematical representation of the amplitude of the signal as a function of frequency. It performs the spectral analysis of the signal for a series of time samples or windows such that the amplitude of the represented frequencies can be plotted over time for the entire signal, as in a spectrogram. After performing the spectral analysis over the entire signal, the system takes a user-selectable subset of successive time samples for which the spectral analysis has been performed, and computes the average amplitude over these samples for each frequency represented in the spectral analysis.

The system then compares the set of averaged amplitudes to one of a plurality of sets of averaged amplitudes computed from spectral analyses stored in a data base. The data base can include a single signal from a speaker or multiple signals from the same speaker using the same device, different devices, devices with channel differences, or different modes within a device. By creating a large data base, the system improves the chances of finding a match among the signal sources within the data base. Comparing the two sets of averaged amplitudes as a ratio of the averaged amplitudes of the stored signal over the averaged amplitudes of the signal associated with the unknown source produces equalization coefficients, which the system then applies to the entire output of the spectral analysis associated with the unknown source, creating an equalized frequency response. Once the system has the equalized frequency response, the system can compare the equalized frequency response to the stored frequency response using a classifier or any other comparison methodology to determine a match. The match can be an affirmative match, a negative match, an affirmative confidence score, a negative confidence score, a percentage match, etc.

When the quality of the stored signal is higher than the quality of the signal associated with an unknown source, the system can produce more accurate results by following an alternate method. After the system has produced the equalization coefficients the system can apply the inverse of the equalization coefficients to the stored frequency response rather than to the frequency response of the signal associated with an unknown source, thereby creating an equalized stored frequency response. The system then compares the equalized stored frequency response to the frequency response associated with an unknown source using the classifier or any other comparison methodology to determine a match. The system chooses whether to apply the equalization coefficients to the frequency response associated with an unknown source or to the stored frequency response based on the relative qualities of the signal associated with an unknown source and the stored signal associated with the stored frequency response. Various embodiments of the disclosure are described in detail below. While specific implementations are described, it should be understood that this is done for illustration purposes only. A person skilled in the relevant art will recognize that other components and configurations can be used without parting from the spirit and scope of the disclosure.

Regarding equalization and normalization, the term “normalization” is commonly used with reference to CMS and RASTA filtering (common industry noise filtering methods) since the intention is to remove the unknown signal noise in order to “normalize” the test signal to that of a clean signal that does not have noise. In these cases the frequency response is not changed, and “normalization” is used to describe adjusting a scale to some normal form, without changing the shape of the distribution curve. Therefore, when normalizing, distributions of different sets are adjusted to the same amplitudes.

By contrast, equalization adjusts an unknown signal's frequency response to conform to a known signal's frequency response. By applying equalization coefficients, the shape of the frequency response for the unknown signal may be changed. Therefore “equalization” is used in performing individual signal adjustments as in a stereo equalizer, where the resulting adjusted curve is equalized to either a standard or to equal amplitudes for selected frequencies.

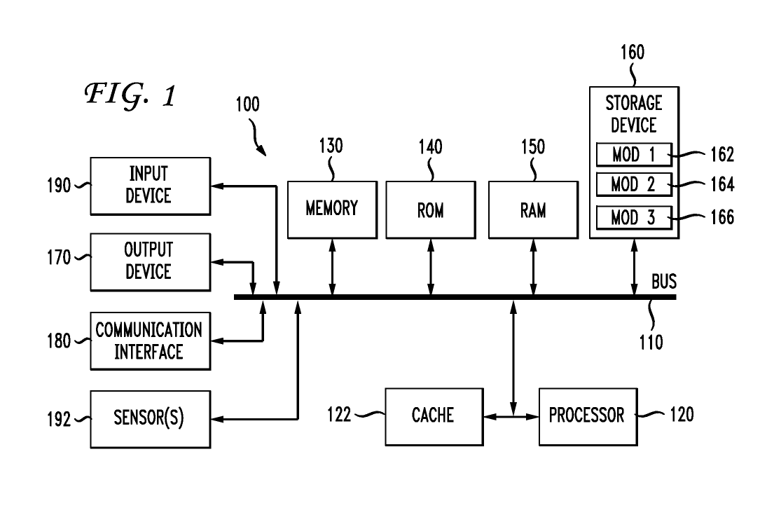

The present disclosure addresses the need in the art for a more accurate method of identifying the source of a signal with channel equalization issues, which can be caused by unknown communications devices, unknown channel conditions, and/or a combination of these and other factors that can affect the frequency response for a signal. A brief introductory description of a basic general purpose system or computing device in FIG. 1 which can be employed to practice the concepts is disclosed herein. A more detailed description of using characteristics of a signal associated with an unknown source to improve the accuracy of identifying the source of the signal will then follow. These variations shall be described herein as the various embodiments are set forth. The disclosure now turns to FIG. 1.

With reference to FIG. 1, an exemplary system 100 includes a general-purpose computing device 100, including a processing unit (CPU or processor) 120 and a system bus 110 that couples various system components including the system memory 130 such as read only memory (ROM) 140 and random access memory (RAM) 150 to the processor 120. The system 100 can include a cache 122 of high speed memory connected directly with, in close proximity to, or integrated as part of the processor 120. The system 100 copies data from the memory 130 and/or the storage device 160 to the cache 122 for quick access by the processor 120. In this way, the cache provides a performance boost that avoids processor 120 delays while waiting for data. These and other modules can control or be configured to control the processor 120 to perform various actions. Other system memory 130 can be available for use as well. The memory 130 can include multiple different types of memory with different performance characteristics. It can be appreciated that the disclosure can operate on a computing device 100 with more than one processor 120 or on a group or cluster of computing devices networked together to provide greater processing capability. The processor 120 can include any general purpose processor and a hardware module or software module, such as module 1 162, module 2 164, and module 3 166 stored in storage device 160, configured to control the processor 120 as well as a special-purpose processor where software instructions are incorporated into the actual processor design. The processor 120 can essentially be a completely self-contained computing system, containing multiple cores or processors, a bus, memory controller, cache, etc. A multi-core processor can be symmetric or asymmetric.

The system bus 110 can be any of several types of bus structures including a memory bus or memory controller, a peripheral bus, and a local bus using any of a variety of bus architectures. A basic input/output (BIOS) stored in ROM 140 or the like, can provide the basic routine that helps to transfer information between elements within the computing device 100, such as during start-up. The computing device 100 further includes storage devices 160 such as a hard disk drive, a magnetic disk drive, an optical disk drive, tape drive or the like. The storage device 160 can include software modules 162, 164, 166 for controlling the processor 120. Other hardware or software modules are contemplated. The storage device 160 is connected to the system bus 110 by a drive interface. The drives and the associated computer-readable storage media provide nonvolatile storage of computer-readable instructions, data structures, program modules and other data for the computing device 100. In one aspect, a hardware module that performs a particular function includes the software component stored in a non-transitory computer-readable medium in connection with the necessary hardware components, such as the processor 120, bus 110, display 170, and so forth, to carry out the function. The basic components are known to those of skill in the art and appropriate variations are contemplated depending on the type of device, such as whether the device 100 is a small, handheld computing device, a desktop computer, or a computer server.

Although the exemplary embodiment described herein employs the hard disk 160, it should be appreciated by those skilled in the art that other types of computer-readable media which can store data that are accessible by a computer, such as magnetic cassettes, flash memory cards, digital versatile disks, cartridges, random access memories (RAMs) 150, read only memory (ROM) 140, a cable or wireless signal containing a bit stream and the like, can also be used in the exemplary operating environment. Non-transitory computer-readable storage media expressly exclude media such as energy, carrier signals, electromagnetic waves, and signals per se.

To enable user interaction with the computing device 100, an input device 190 represents any number of input mechanisms, such as a microphone for speech, a touch-sensitive screen for gesture or graphical input, keyboard, mouse, motion input, speech and so forth. An output device 170 can also be one or more of a number of output mechanisms known to those of skill in the art. In some instances, multimodal systems enable a user to provide multiple types of input to communicate with the computing device 100. The communications interface 180 generally governs and manages the user input and system output. There is no restriction on operating on any particular hardware arrangement and therefore the basic features here can easily be substituted for improved hardware or firmware arrangements as they are developed.

For clarity of explanation, the illustrative system embodiment is presented as including individual functional blocks including functional blocks labeled as a “processor” or processor 120. The functions these blocks represent can be provided through the use of either shared or dedicated hardware, including, but not limited to, hardware capable of executing software and hardware, such as a processor 120, that is purpose-built to operate as an equivalent to software executing on a general purpose processor. For example the functions of one or more processors presented in FIG. 1 can be provided by a single shared processor or multiple processors. (Use of the term “processor” should not be construed to refer exclusively to hardware capable of executing software.) Illustrative embodiments can include microprocessor and/or digital signal processor (DSP) hardware, read-only memory (ROM) 140 for storing software performing the operations described below, and random access memory (RAM) 150 for storing results. Very large scale integration (VLSI) hardware embodiments, as well as custom VLSI circuitry in combination with a general purpose DSP circuit, can also be provided.

The logical operations of the various embodiments are implemented as: (1) a sequence of computer implemented steps, operations, or procedures running on a programmable circuit within a general use computer, (2) a sequence of computer implemented steps, operations, or procedures running on a specific-use programmable circuit; and/or (3) interconnected machine modules or program engines within the programmable circuits. The system 100 shown in FIG. 1 can practice all or part of the recited methods, can be a part of the recited systems, and/or can operate according to instructions in the recited non-transitory computer-readable storage media. Such logical operations can be implemented as modules configured to control the processor 120 to perform particular functions according to the programming of the module. For example,

FIG. 1 illustrates three modules Mod1 162, Mod2 164 and Mod3 166 which are modules configured to control the processor 120. These modules can be stored on the storage device 160 and loaded into RAM 150 or memory 130 at runtime or can be stored as would be known in the art in other computer-readable memory locations.

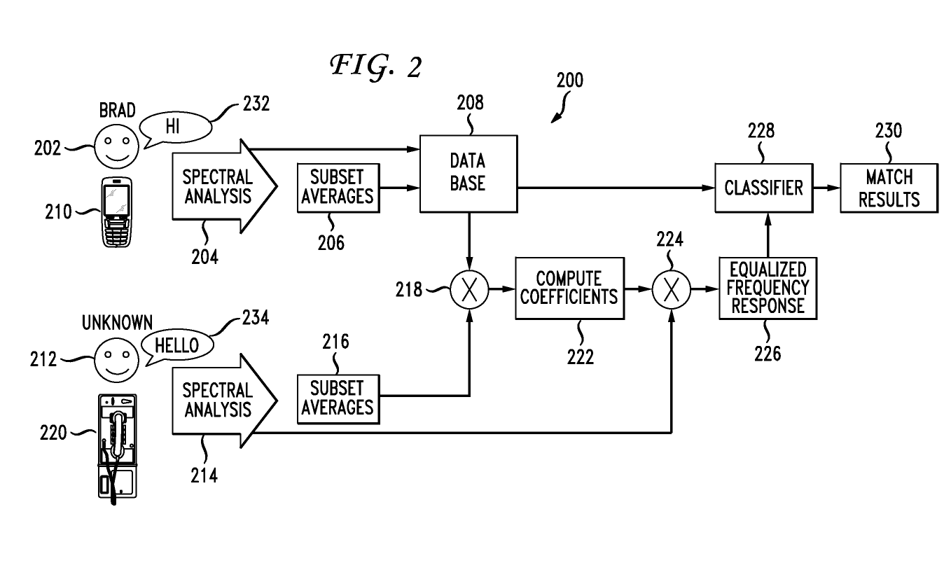

Having disclosed some components of a computing system, the disclosure now turns to FIG. 2, which illustrates a system 200 configured according to this disclosure to perform signal identification when the equalization coefficients are applied to a signal from an unknown entity. In this example the signal is a spoken utterance 232 of the known speaker 202, where the known speaker 202 says “Hi” 232 into the communications device 210. The spoken utterance 232 is recorded either by the system 200, or it is provided to the system 200. The system 200 performs a spectral analysis 204 of the spoken utterance 232, and uses the spectral analysis 204 to compute, from a user-selectable subset of successive time samples of the spectral analysis, the average amplitude over these samples for each represented frequency 206 for the spoken utterance 232. The system stores the set of averaged amplitudes 206 and the identity of the known speaker 202 in a data base 208 for later use.

The system 200 performs these steps multiple times for many known speakers in order to create a robust data base for the task of identifying the sources of signals. The data base can include a single signal from a speaker or multiple signals from the same speaker using the same device, different devices, devices with channel differences, or different modes within a device. For example the system can store five samples from speaker A, two from speaker A's home phone one from speaker A's cell phone, and two from speaker A's office phone. The data base can also store a concatenated signal that combines all the signals from the same speaker. For each signal stored in the data base, the data base also stores the spectral analysis, the sets of averaged amplitudes computed from the spectral analyses, and the identity of the origin of the signal where available from metadata accompanying the audio file containing the signal By creating a large data base, the system 200 improves the chances of finding a match among the signal sources within the data base.

The signals can be a spoken utterance, a conversation, a sound, an audio, a video, a sonar signal, a light wave, an electromagnetic signal, etc. The signal is communicated using a known or unknown communications device 210. The communications device 210 can be one of a phone, a microphone, a cell phone, a smartphone, a desktop terminal, a laptop, a landline, a satellite, a satellite dish, a sonar transmitter, a sonar receiver, an antenna, a camera, a video display, a walkie-talkie, a photocell, optical sensors, or any other device capable of receiving or transmitting signals. The signal does not always need to be associated with a speaker but can be associated with a vehicle, a plane, a boat, or any other signal generating machine, device, animal, material, etc. The data base can also store signals without a known source which can be used to identify signal from the same unknown source.

After the system 200 has compiled the data base 208, the system 200 receives a signal 234 from an unknown speaker 212, which in this case is the spoken utterance “Hello” 234. The signal is communicated or recorded via an unknown communications device 220. Next, the system 200 performs a spectral analysis 214 of the signal 234, and computes the average amplitude over a user-specified subset of successive times samples for each frequency 216 measured (estimated) by the spectral analysis 214. The system 200 then compares 218 the sets of averaged amplitudes 206 stored in the data base 208 with the set of averaged amplitudes 216 associated with the unknown speaker 212 as a ratio of the average amplitudes of the stored signal over the average amplitudes of the signal associated with an unknown source to produce equalization coefficients 222. After computing the equalization coefficients 222, the system 200 applies 224 the equalization coefficients 222 to the entire output of the spectral analysis of the signal 214 associated with the unknown speaker 212, creating an equalized frequency response. 226. The system 200 compares the equalized frequency response 226 to the frequency response 204 stored in the data base 208 using a classifier 228 to determine a match 230.

The classifier, employing common methods for signal classification such as Gaussian Mixture Models (GMM), alone or in combination with Hidden Markov Models (HMM) and Support Vector Machines (SVM); artificial neural networks (ANN); or any of a variety of other standard recognition methodologies, is used to perform the comparison. The match can be an affirmative match, a negative match, an affirmative confidence score, a negative confidence score, a percentage match, etc. These steps can be performed for each signal stored in the data base until every signal in the data base has been compared, a match has been found, or a user or a triggering event cancels the process. If there is more than one stored signal for a speaker, then the system can compare the signal associated with an unknown source to each stored signal separately or to a concatenation of the stored signal, or to the separate files and a concatenation.

If the signals have the same source, and channel differences exist, then the system causes the frequency response associated with an unknown source to match, or more closely match, the frequency response of the stored signal. This creates a stronger and more accurate positive match. If the signals do not have the same source, and channel differences exist, then the system distorts the frequency response of the unknown signal with further clarity. This creates a stronger and more accurate negative match. The system makes no assumptions on the signals to be equalized. The system equalizes the signals amongst themselves but requires no equalization to a common flat response.

This example assumes that the captured signal contains only the signal to be identified. This is not always the case. The system can receive a signal with background sounds and other non-speaker audio that can reduce the accuracy of the identification. This issue can be mitigated by using a segmenter that marks each segment that contains only the speaker voice, discounting periods of other noise. The segmenter can be configured to detect the portion of the signal to be identified or the segmenter can be configured to detect the portion of the signal to be rejected, or the segmenter can do a combination of both. When the background signal is a continuous noise such as from an air conditioner the system 200 identifies the continuous background noise and accommodates for the frequency components affected by the continuous background noise. If the noise components interfere too much with a range of frequencies, then the range of frequencies needs to be discarded from evaluation in order to focus on the unaffected frequencies. Discarding frequencies reduces the data to be analyzed, but increases accuracy by removing the overwhelming noise. There may also be instances in which the spectral characteristics of the device alone can be thought of as the signal for which the source needs to be indentified. Use of the segmenter here can isolate portions of the signal that contain only the spectral characteristics of the device itself, for use in its identification.

The source of the signal can be either cooperative or uncooperative. For example, when the system 200 identifies a speaker, the speaker might be unaware that they are being recorded. In some cases a caller, who calls a call center, can receive a message that informs the caller that the call will be recorded and by staying on the line the caller has given consent to be recorded. Alternately, the police can have a legal wiretap which allows them to listen to conversations where the speaker does not have any knowledge of the recording. Using characteristics of a signal associated with an unknown source to improve the accuracy of identifying the source of a signal can be useful for many types of signal identification that go beyond any of the specific examples stated herein. Any signal identification where the signals have channel inequalities can benefit from the increased accuracy of the present invention.

Using characteristics of a signal associated with an unknown source to improve the accuracy of identifying the source can aid in detecting intentional deception. Identifying a speaker on several different communications modes can indicate attempts to avoid detection by the use of many different communications devices. The varying communications modes can be logged in the data base to track the variety and quantity of devices used by a single source. The differences in frequency response can help to identify the specific communications device, which can also be stored in the data base. This would apply as well to those instances in which the spectral characteristics of the device alone can be thought of as a signal whose source needs to be identified.

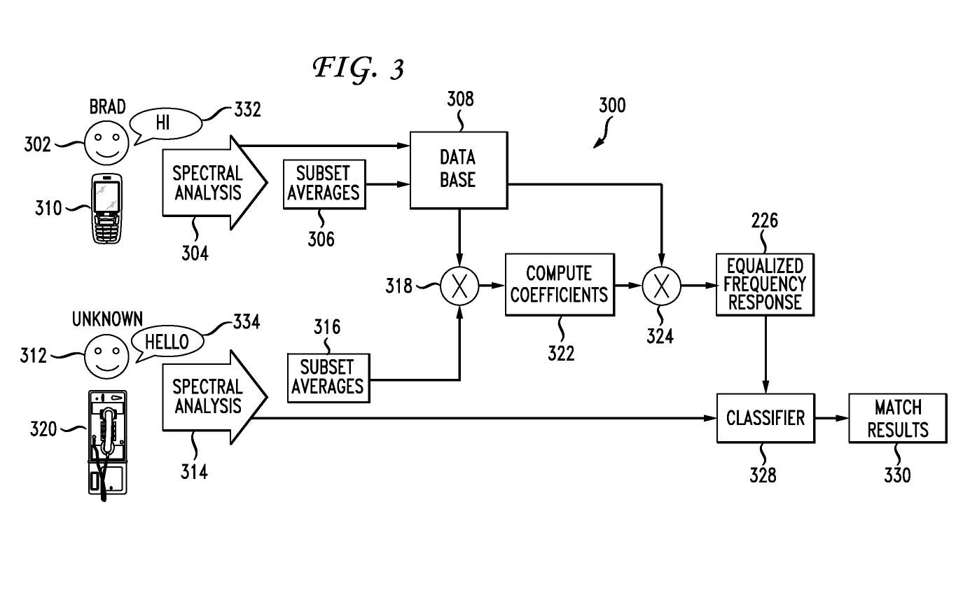

FIG. 3 illustrates exemplary signal identification when the equalization coefficients are applied to a stored frequency response associated with a stored signal. When the stored frequency response is of a higher quality than the frequency response associated with an unknown source, accuracy improves by applying the equalization coefficients to the stored frequency response. The system 300, configured according to this disclosure to perform signal identification, receives a signal, which in this example is a spoken utterance “Hi” 332, from a speaker 302 into a communications device 310. The system 300 performs a spectral analysis 304 of the spoken utterance 332, and uses the spectral analysis 304 to compute, from a user-selectable subset of successive time samples of the spectral analysis, the average amplitude over these samples for each represented frequency 306 for the spoken utterance 332. The system stores the set of averaged amplitudes 306 and the identity of the known speaker 302 in a data base 308 for later use.

The system 300 performs these steps multiple times for many known speakers in order to create a robust data base for the task of identifying the source of a signal. The data base can include a single signal from a speaker or multiple signals from the same speaker using the same device or different devices. For example the system can store five samples from speaker A, two from speaker A's home phone one from speaker A's cell phone, and two from speaker A's office phone. The data base can also store a concatenated signal that combines all the signals from the same speaker. For each signal stored in the data base, the data base also stores the spectral analysis, the sets of averaged amplitudes computed from the spectral analyses, and the identity of the origin of the signal, where available from metadata accompanying the audio file containing the signal. By creating a large data base, the system 300 improves the chances of finding a match among the signal sources within the data base.

The signals can be a spoken utterance, a conversation, a sound, an audio, a video, a sonar signal, a light wave, an electromagnetic signal, etc. The signal is communicated using a known or unknown communications device 310. The communications device 310 can be one of a phone, a microphone, a cell phone, a smartphone, a desktop terminal, a laptop, a landline, a satellite, a satellite dish, a sonar transmitter, a sonar receiver, an antenna, a camera, a video display, a walkie-talkie, a photocell, optical sensors, or any other device capable of receiving or transmitting signals. The signal does not always need to be associated with a speaker but can be associated with a vehicle, a plane, a boat, or any other signal generating machine, device, animal, material, etc. The data base can also store signals without a known association which can be used to identify signal from the same unknown source.

After the system 300 has compiled the data base 308, the system 300 receives a signal 334 from an unknown speaker 312, which in this case is the spoken utterance “Hello” 334. The signal is communicated or recorded via an unknown communication device 320. Next, the system 300 performs a spectral analysis 314 of the of the entire signal 334 associated with the unknown speaker 312, and computes the average amplitude over a user-specified subset of successive times samples for each frequency 316 measured (estimated) by the spectral analysis. The system 300 then compares 318 the averaged amplitudes 304 stored in the data base 308 with the averaged amplitudes 314 associated with the unknown speaker 312 as a ratio of the averaged amplitudes of the stored signal over the averaged amplitudes of the signal associated with an unknown source to compute equalization coefficients 322. After computing the equalization coefficients 222, the system 300 applies 324 the inverse of the equalization coefficients 322 to the frequency response 304, stored in the data base 308, creating an equalized stored frequency response 326. The system 300 compares the equalized stored frequency response 326 to the frequency response 314 associated with the unknown speaker 312 using a classifier 328 to determine a match 330.

The classifier is one method for comparison and the comparison can be performed using any comparison methodology. The match can be an affirmative match, a negative match, an affirmative confidence score, a negative confidence score, a percentage match, etc. These steps can be performed for each signal stored in the data base until every signal in the data base has been compared, a match has been found, or a user or a triggering event cancels the process. If there is more than one stored signal for a speaker then the system can compare the signal 334 associated with the unknown speaker 312 to each signal separately or to a concatenation of the stored signal, or to the separate files and a concatenation.

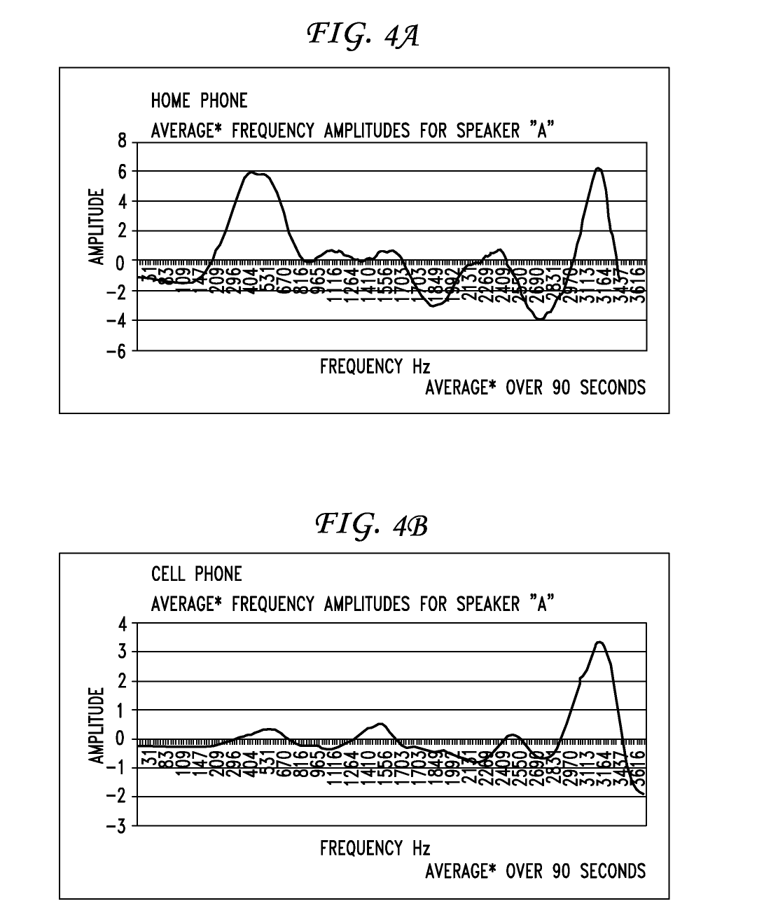

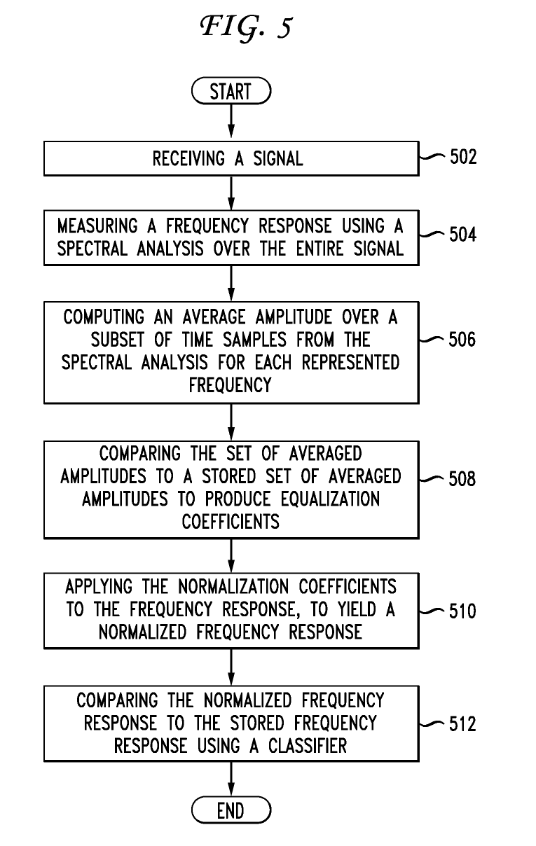

FIGS. 4a-4b illustrate exemplary frequency responses all taken from the same speaker using different communications devices for each figure. FIG. 4a depicts a plot of an actual set of averaged amplitudes computed for each represented frequency in a spectral analysis of the voice of a speaker speaking into his home phone. FIG. 4b depicts a plot of an actual set of averaged amplitudes of the same speaker speaking into his cell phone. The system can smooth these plots to remove some of the fluctuations prior to comparing or analyzing by the system. After completing the method of FIG. 5, the match shows a positive match or a high degree of confidence, because these samples were in fact from the same person.

Having disclosed some basic system components and concepts, the disclosure now turns to the exemplary method embodiment shown in FIG. 5. For the sake of clarity, the method is described in terms of an exemplary system 100 as shown in FIG. 1 configured to practice the method. The steps outlined herein are exemplary and can be implemented in any combination thereof, including combinations that exclude, add, or modify certain steps. A system 100 receives a signal (502). The system 100 measures a frequency response of the signal by performing a spectral analysis over the entire signal (504). The system 100 then computes from a user-selectable subset of successive time samples for which the spectral analysis has been performed, the average amplitude over these samples for each represented frequency (506). The system then compares the averaged amplitudes of the received signal to the averaged amplitudes of a stored signal as a ratio of the averaged amplitudes of the stored signal over the averaged amplitudes of the received signal to produce equalization coefficients (508). The system 100 applies the equalization coefficients to the frequency response, to yield an equalized frequency response (510). Finally, the system 100 compares the equalized frequency response to the stored frequency response using a classifier (512) or any other comparison methodology.

Alternately, the system 100 applies the inverse of the equalization coefficients, not to the frequency response of the signal associated with an unknown source, but rather to the stored frequency response to yield n equalized stored frequency response, and then compares the equalized stored frequency response to the frequency response associated with an unknown source using a classifier or any other comparison methodology. These alternate steps can be beneficial when the stored signal is of a higher quality than the signal associated with an unknown source.

Embodiments within the scope of the present disclosure can also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor as described above. By way of example, and not limitation, such non-transitory computer-readable media can include RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Those of skill in the art will appreciate that other embodiments of the disclosure can be practiced in network computing environments with many types of computer system configurations, including personal computers, hand-held devices, multi-processor systems, microprocessor-based or programmable consumer electronics, network PCs, minicomputers, mainframe computers, and the like. Embodiments can also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various embodiments described above are provided by way of illustration only and should not be construed to limit the scope of the disclosure. For example, the principles herein apply equally to determining the identity of a speaker from a spoken utterance as they do to determining the make and model of a vehicle based on the sound from the engine, as well as identifying the species of a bird based on a call that was recorded on an unknown cell phone. Those skilled in the art will readily recognize various modifications and changes that can be made to the principles described herein without following the example embodiments and applications illustrated and described herein, and without departing from the spirit and scope of the disclosure.

We claim:

1. A method comprising:
receiving a signal;
estimating a frequency response by performing a spectral analysis of the signal;
computing average amplitudes over a user-selectable subset of time samples for each frequency estimated by the spectral analysis;
comparing the averaged amplitudes to a stored set of averaged amplitudes, to yield equalization coefficients;
applying the equalization coefficients to the frequency response, to yield an equalized frequency response; and
comparing the equalized frequency response to a stored frequency response using a classifier.

2. The method of claim 1, wherein comparing the equalized frequency response to the stored frequency response yields a match result that indicates whether a match exists between the signal and a stored signal associated with the stored frequency response.

3. The method of claim 1, wherein the signal is one of a spoken utterance, a conversation, a sound, an audio, a video, a sonar signal, a light wave, and an electromagnetic signal.

4. The method of claim 2, wherein the match result is one of an affirmative match, a negative match, an affirmative confidence score, a negative confidence score, and a percentage match.

5. The method of claim 1, the method further comprising:
applying the equalization coefficients to the stored frequency response, to yield an equalized stored frequency response; and
determining an alternate match by comparing the equalized stored frequency response to the frequency response using a classifier.

6. The method of claim 1, wherein the signal is associated with an unidentified speaker.

7. The method of claim 1, wherein the stored frequency response is associated with an identified speaker.

8. A system comprising:
a processor; and
a computer-readable storage medium having instructions stored which, when executed by the processor, cause the processor to perform a method comprising:
receiving a signal;
estimating a frequency response by performing a spectral analysis of the signal;
computing average amplitudes over a user-selectable subset of time samples for each frequency estimated by the spectral analysis;
comparing the averaged amplitudes to a stored set of averaged amplitudes, to yield equalization coefficients;
applying the equalization coefficients to the frequency response, to yield an equalized frequency response; and
comparing the equalized frequency response to a stored frequency response using a classifier.

9. The system of claim 8, wherein comparing the equalized frequency response to the stored frequency response yields a match result that indicates whether a match exists between the signal and a stored signal associated with the stored frequency response.

10. The system of claim 8, wherein the signal is one of a spoken utterance, a conversation, a sound, an audio, a video, a sonar signal, a light wave, and an electromagnetic signal.

11. The system of claim 9, wherein the match result is one of an affirmative match, a negative match, an affirmative confidence score, a negative confidence score, and a percentage match.

12. The system of claim 8, the computer-readable storage medium having stored additional instructions which result in the method further comprising:
applying the inverse of the equalization coefficients to the stored frequency response, to yield an equalized stored frequency response; and
determining an alternate match by comparing the equalized stored frequency response to the frequency response using a classifier.

13. The system of claim 8, wherein the signal is associated with an unidentified speaker.

14. The system of claim 8, wherein the stored frequency response is associated with an identified speaker.

15. A computer-readable storage medium storing instructions which, when executed by a computing device, cause the computing device to perform a method comprising:
receiving a signal;
estimating a frequency response by performing a spectral analysis of the signal;
computing average amplitudes over a user-selectable subset of time samples for each frequency estimated by the spectral analysis;
comparing the averaged amplitudes to a stored set of averaged amplitudes, to yield equalization coefficients;
applying the equalization coefficients to the frequency response, to yield an equalized frequency response; and
comparing the equalized frequency response to a stored frequency response using a classifier.

16. The computer-readable storage medium of claim 15, wherein comparing the equalized frequency response to the stored frequency response yields a match result that indicates whether a match exists between the signal and a stored signal associated with the stored frequency response.

17. The computer-readable storage medium of claim 15, wherein the signal is one of a spoken utterance, a conversation, a sound, an audio, a video, a sonar signal, a light wave, and an electromagnetic signal.

18. The computer-readable storage medium of claim 16, wherein the match result is one of an affirmative match, a negative match, an affirmative confidence score, a negative confidence score, and a percentage match.

19. The computer-readable storage medium of claim 15, the computer-readable storage medium having additional instructions stored which result in the method further comprising:
applying the inverse of the equalization coefficients to the stored frequency response to yield an equalized stored frequency response; and
determining an alternate match by comparing the equalized stored frequency response to the frequency response using a classifier.

20. The computer-readable storage medium of claim 15, wherein the signal is associated with an unidentified speaker.
